(19) United States
(12) Patent Application Publication
(10) Pub. No.: US 2015/0072075 A1
(43) Pub. Date: Mar. 12, 2015

(54) FILM-FORMING APPARATUS AND FILM-FORMING METHOD

(71) Applicant: TOKYO ELECTRON LIMITED, Minato-ku (JP)

(72) Inventor: Norio WADA, Koshi-shi (JP)

(73) Assignee: TOKYO ELECTRON LIMITED, Minato-ku (JP)

(21) Appl. No.: 14/541,510

(22) Filed: Nov. 14, 2014

Related U.S. Application Data
(63) Continuation of application No. PCT/JP2013/063632, filed on May 16, 2013.

(30) Foreign Application Priority Data
May 16, 2012 (JP) 2012-112653

(51) Int. Cl. C23C 16/448; C23C 16/44

(52) U.S. Cl. CPC C23C 16/4486; C23C 16/4412
USPC 427/255.23; 118/715; 118/726; 118/729

(57) ABSTRACT

A film-forming apparatus includes an aerosol generation device which generates an aerosol including a solution of a film-forming material dispersed in a carrier gas, a chamber which vaporizes the aerosol such that fine particles of the film-forming material are generated from the aerosol that is generated by the aerosol generation device, a nozzle which discharges the fine particles generated by the chamber toward a substrate, and a moving mechanism which executes relative movement of the nozzle and the substrate along a surface of the substrate. The nozzle has a discharge port which discharges the fine particles to a slit-shaped region extending in a direction orthogonal to a moving direction of the relative movement between the nozzle and the substrate executed by the moving mechanism.

### CROSS-REFERENCE TO RELATED APPLICATIONS

The present application is continuation of PCT/JP2013/063632, filed May 16, 2013, which is based upon and claims the benefit of priority to Japanese Patent Application No. 2012-112653, filed May 16, 2012. The entire contents of these applications are incorporated herein by reference.

### BACKGROUND OF THE INVENTION

1. Field of the Invention

Embodiments of the disclosure relate to a film-forming apparatus and a film-forming method.

2. Description of Background Art

There is a film-forming method in which fine particles of a raw material are generated by aerosolizing a solution that contains the raw material and vaporizing a solvent in the aerosol, and are attached to a substrate, thereby forming a thin film on the substrate (see Japanese Patent No. 3541294). Specifically, in the technology described in Japanese Patent No. 3541294, a thin film is formed on a substrate by performing, for multiple times while shifting a line, a scan coating operation in which coating is performed by moving the substrate in a certain direction while discharging fine particles from a nozzle toward the substrate. In the technology described in Japanese Patent No. 3541294, the scan coating operation is performed using a nozzle on which a circular discharge port is formed. The entire contents of this publication are incorporated herein by reference.

### SUMMARY OF THE INVENTION

According to one aspect of the present invention, a film-forming apparatus includes an aerosol generation device which generates an aerosol including a solution of a film-forming material dispersed in a carrier gas, a chamber which vaporizes the aerosol such that fine particles of the film-forming material are generated from the aerosol that is generated by the aerosol generation device, a nozzle which discharges the fine particles generated by the chamber toward a substrate, and a moving mechanism which executes relative movement of the nozzle and the substrate along a surface of the substrate. The nozzle has a discharge port which discharges the fine particles to a slit-shaped region extending in a direction orthogonal to a moving direction of the relative movement between the nozzle and the substrate executed by the moving mechanism.

According to another aspect of the present invention, a method for forming a film includes generating an aerosol including a solution of a film-forming material dispersed in a carrier gas by an aerosol generation device, vaporizing the aerosol in a chamber such that fine particles of the film-forming material is generated from the aerosol that is generated by the aerosol generation device, and discharging the fine particles generated by the chamber from a nozzle toward a substrate. The discharging of the fine particles includes discharging the fine particles to a slit-shaped region extending in a direction orthogonal to a movement direction of relative movement of the nozzle and the substrate while a moving mechanism executes the relative movement of the nozzle and the substrate along a surface of the substrate.

### BRIEF DESCRIPTION OF THE DRAWINGS

A more complete appreciation of the invention and many of the attendant advantages thereof will be readily obtained as the same becomes better understood by reference to the following detailed description when considered in connection with the accompanying drawings, wherein:

FIG. 1 illustrates a schematic diagram illustrating a structure of a film-forming apparatus according to a first embodiment;

FIG. 2A illustrates a schematic plan view illustrating a shape of a nozzle according to the first embodiment;

FIG. 2B illustrates a schematic side view illustrating the shape of the nozzle according to the first embodiment;

FIG. 3A illustrates a schematic diagram illustrating an operation example of a scan coating operation;

FIG. 3B illustrates a schematic diagram illustrating an operation example of a scan coating operation;

FIG. 3C illustrates a schematic diagram illustrating an operation example of a scan coating operation;

FIG. 4 illustrates a block diagram of the film-forming apparatus;

FIG. 5 illustrates a flow chart illustrating processing steps of a film-forming process that the film-forming apparatus executes;

FIG. 6 illustrates a schematic diagram illustrating a structure of a film-forming apparatus according to a second embodiment;

FIG. 7A illustrates a schematic diagram illustrating an operation example of a scan coating operation according to the second embodiment;

FIG. 7B illustrates a schematic diagram illustrating an operation example of a scan coating operation according to the second embodiment;

FIG. 7C illustrates a schematic diagram illustrating an operation example of a scan coating operation according to the second embodiment;

FIG. 8 illustrates a schematic diagram illustrating a connection relationship between a first chamber and a recovery part according to a third embodiment;

FIG. 9A illustrates a schematic plan view illustrating another shape of a nozzle; and

FIG. 9B illustrates a schematic plan view illustrating another shape of a nozzle.

### DETAILED DESCRIPTION OF THE EMBODIMENTS

The embodiments will now be described with reference to the accompanying drawings, wherein like reference numerals designate corresponding or identical elements throughout the various drawings.

### First Embodiment

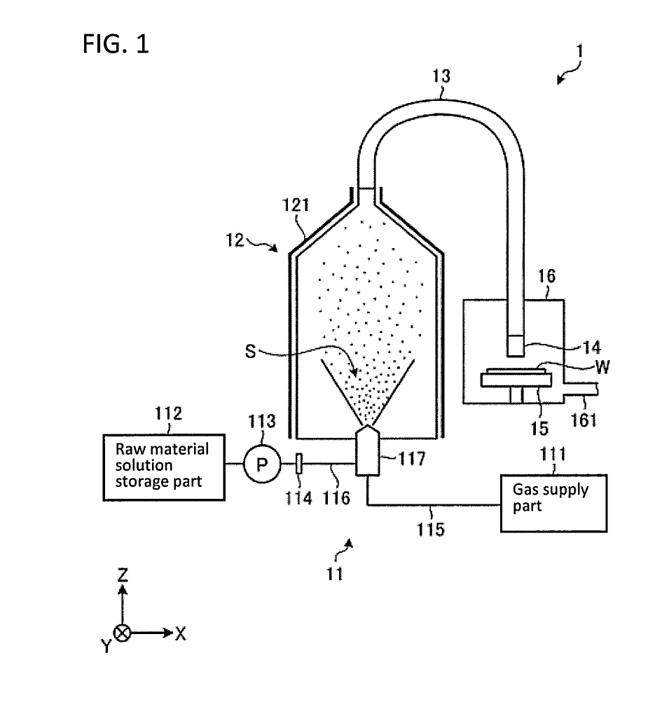

FIG. 1 illustrates a schematic diagram illustrating a structure of a film-forming apparatus according to a first embodiment. A film-forming apparatus 1 illustrated in FIG. 1 is a device that forms on a substrate (W) an organic thin film that forms an organic EL (Electro-Luminescence) element. The film-forming apparatus 1 includes an aerosol generation part 11, a first chamber 12, a pipe 13, a nozzle 14, a stage 15, and a second chamber 16.

In the following, in order to clarify a positional relation, mutually orthogonal X-axis, Y-axis and Z-axis are defined and a positive direction of the Z-axis is defined as being vertically upward.

The aerosol generation part 11 is a member that generates an aerosol (S) that is obtained by dispersing a solution of an organic material that is a film-forming material in a carrier gas.

The organic material contained in the aerosol (S) is, for example, polyphenylene vinylene (MEH-PPV), polyfluorene, tris-quinolinolate aluminum, or the like, but is not limited to these and can be any compound that is dissolved or dispersed at a concentration of about 0.001% in a solvent. In the following, the solution of the organic material is referred to as a “raw material solution.” Further, the carrier gas is an inert gas such as a nitrogen gas, an argon gas and a helium gas, or air.

The aerosol generation part 11 includes a gas supply part 111, a raw material solution storage part 112, a raw material solution supply part 113, a filter 114, pipes 115, 116, and a spraying device 117

The gas supply part 111 supplies the carrier gas via the pipe 115 to the spraying device 117. The gas supply part 111 includes, for example, a gas cylinder that stored the carrier gas and a controller that is connected to the gas cylinder and controls a flow rate and pressure of the carrier gas.

The raw material solution storage part 112 is a tank that stores the raw material solution and is connected via the pipe 116 to the spraying device 117. The raw material solution that is stored in the raw material solution storage part 112 is sucked up from the raw material solution storage part 112 by the raw material solution supply part 113 that is provided at a middle portion of the pipe 116 and is supplied to the spraying device 117. The raw material solution supply part 113 includes, for example, a pump and a controller controlling the pump.

At a middle portion of the pipe 116, the filter 114 is provided. The filter 114 is, for example, a filter having an opening diameter of 0.5 μm and removes foreign substances contained in the raw material solution.

The spraying device 117 mixes and sprays the carrier gas that is supplied from the gas supply part 111 and the raw material solution that is supplied from the raw material solution storage part 112, and thereby generates the aerosol (S) in which the raw material solution is suspended as liquid particles of sizes of about 1-100 μm in the carrier gas.

The spraying device 117 is fixed in a state in which a front end part thereof including a spray port penetrates through a base end part of the first chamber 12 and protrudes into the first chamber 12. As a result, the aerosol (S) that is generated by the aerosol generation part 11 is supplied into the first chamber 12.

Here, the aerosol generation part 11 uses the spraying device 117 to generate the aerosol S. However, it is also possible that the aerosol generation part uses a member other than the spraying device to generate the aerosol (S). For example, it is also possible that the aerosol generation part uses ultrasonic vibration to generate the aerosol.

The first chamber 12 is a container that has a cylindrical guide passage. The first chamber 12 is formed to have a large diameter so as not to hinder a flow of the aerosol S. A circular opening part is formed at a front end part of the first chamber 12, and one end part of the pipe 13 is connected to the opening part. The pipe 13 is, for example, a rubber pipe. The first chamber 12 and the nozzle 14 are connected by the pipe 13.

A heating part 121 such as an electric heater is provided on an outer peripheral surface of the first chamber 12. Due to the heating part 121, a temperature in the first chamber 12 is maintained at a temperature suitable for vaporization of the solvent contained in the aerosol (S).

The aerosol S that is supplied by the aerosol generation part 11 into the first chamber 12 is sent from the base end part to the front end part of the first chamber 12 by the carrier gas that is supplied from the gas supply part 111. During this process, the solvent contained in the aerosol (S) is removed by vaporization and, as a result, fine particles of the organic material having particle diameters of about 10-1000 nm are generated. The generated fine particles of the organic material are supplied from the front end part of the first chamber 12 via the pipe 13 to the nozzle 14.

The first chamber 12 is installed in a vertical orientation, that is, an orientation in which the base end part becomes a bottom part. As a result, among the generated fine particles of the organic material, particles having large particle diameters fall due to gravity and are unlikely to reach the front end part of the first chamber 12. Therefore, by arranging the first chamber 12 in the vertical orientation, the particle diameters of the fine particles of the organic material that are supplied to the nozzle 14 can be equalized.

The nozzle 14 is a member that is arranged above the stage 15 that holds the substrate (W) in a horizontal orientation, and discharges the fine particles of the organic material toward a surface of the substrate (W) on the stage 15. The stage 15 is, for example, a suction holding part that suction-holds the substrate (W), and moves in horizontal directions (X-axis direction and Y-axis direction) due to a moving mechanism (to be described later).

In the first embodiment, the substrate (W) is a glass substrate on a surface of which an indium tin oxide transparent conductive thin film (hereinafter referred to as an “ITO thin film”) is formed. The substrate (W) may also be a glass substrate on a surface of which a thin film of a metal such as gold or aluminum is formed, or a substrate other than a glass substrate such as a silicon substrate.

The nozzle 14, the stage 15 and the substrate (W) are arranged in the second chamber 16. The second chamber 16 includes an exhaust part 161. From the exhaust part 161, the carrier gas, the fine particles of the organic material that are not applied to the substrate (W), and the like, are discharged.

The film-forming apparatus 1 performs scan coating with respect to the substrate (W) by using the moving mechanism to move the stage 15 while discharging the fine particles of the organic material from the nozzle 14 toward the surface of the substrate (W). As a result, the fine particles of the organic material are attached to the surface of the substrate (W) and an organic thin film is formed.

In the case where a scan coating operation is performed, when the discharge port has a circular shape, it is difficult to perform coating in a broad area in one scan coating operation. Therefore, in the film-forming apparatus 1 according to the first embodiment, the discharge port of the nozzle 14 is formed in a slit shape and thereby coating in a broad area can be performed in one coating operation.

In the film-forming apparatus 1 according to the first embodiment, by devising not only the shape of the discharge port but also a shape of the nozzle 14 itself, film thickness uniformity is improved.

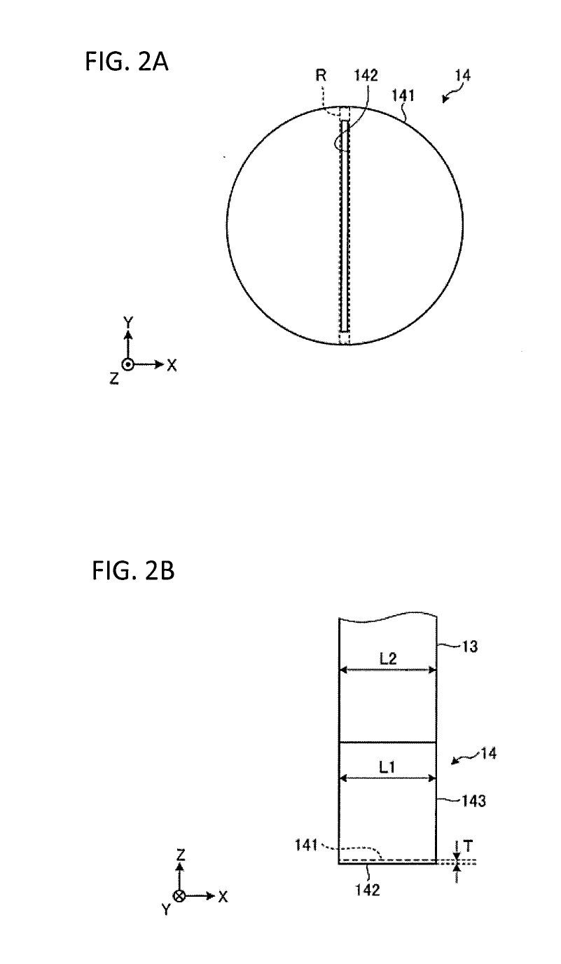

The specific shape of the nozzle 14 is described using FIG. 2A and 2B. FIG. 2A illustrates a schematic plan view illustrating the shape of the nozzle 14 according to the first embodiment; and FIG. 2B illustrates a schematic side view illustrating the shape of the nozzle 14.

FIG. 2A illustrates a shape of a bottom part 141 of the nozzle 14 when viewed from above. The discharge port 142 of the nozzle 14 is formed on the bottom part 141.

As illustrated in FIG. 2A, the discharge port 142 extends in a direction orthogonal to a main scanning direction (X-axis direction) in a scan coating operation. That is, the discharge port 142 is formed wide with respect to the main scanning direction and thus a coating area per one scan coating operation can be increased as compared to a case where the same scan coating operation is performed using a circular discharge port having the same opening area.

The fine particles of the organic material tend to flow along an edge surface of the discharge port. Therefore, when a space between one edge and another edge of the discharge port is large, the fine particles of the organic material are less likely to attach to a portion of the surface of the substrate (W) positioned below this space and thus there is a concern that uneven coating occurs between the portion of the surface of the substrate (W) positioned below this space and portions of the surface of the substrate (W) positioned below the edges of the discharge port.

In contrast, the discharge port 142 of the nozzle 14 according to the first embodiment is formed narrow with respect to a direction (that is, a sub-scanning direction) that is orthogonal to the main scanning direction. That is, two edges of the discharge port 142 that extend in the sub-scanning direction (Y-axis direction) are close to each other. Therefore, the uneven coating as described above can be suppressed and film thickness uniformity can be improved.

The discharge port 142 is not necessarily required to have a slit shape. That is, the discharge port 142 may have a shape other than a slit shape as long as the discharge port 142 is formed in a slit-shaped region (R) that extends in a direction orthogonal to the main scanning direction. It is desirable that a width of the slit-shaped region (R) in the sub-scanning direction be 1 mm or less.

For the nozzle 14 according to the first embodiment, in addition to the discharge port 142, the shape of the nozzle 14 is also devised. This point is described using FIG. 2B. As illustrated in FIG. 2B, the nozzle 14 has a cylindrical body part 143, and the bottom part 141 is formed on one end of the body part 143. As described above, the nozzle 14 is a bottomed cylindrical member, of which the discharge port 142 is formed on the bottom part 141. On the other end of the body part 143, the pipe 13 is connected.

An inner periphery of the body part 143 is formed in a cylindrical shape with an inner diameter (L1) being substantially the same as an inner diameter (L2) of the pipe 13. In this way, in the first embodiment, a flow path of the fine particles of the organic material from the front end part of the first chamber 12 to the discharge port 142 of the nozzle 14 is formed to have substantially the same inner diameter.

When there is a place in the path from the front end part of the first chamber 12 to the discharge port 142 of the nozzle 14 where the inner diameter is different, there is a possibility that, at such a place, turbulence occurs in the flow of the fine particles and the fine particles are not uniformly discharged from the discharge port 142 so that uneven coating occurs.

As in the film-forming apparatus 1 according to the first embodiment, by making the inner diameter (L1) of the body part 143 substantially the same as the inner diameter (L2) of the pipe 13, uneven coating can be suppressed and film thickness uniformity can be improved.

As illustrated in FIG. 2B, the bottom part 141 of the nozzle 14 is formed thin. When the bottom part 141 is formed thick, the discharge port 142 also becomes thick and, as a result, there is a possibility that the fine particles of the organic material attach to inside of the discharge port 142 and clogging, turbulence in air flow, and the like, occur.

As in the film-forming apparatus 1 according to the first embodiment, by forming the bottom part 141 of the nozzle 14 thin, uneven coating can be further suppressed and film thickness uniformity can be improved.

Specifically, when a thickness (T) of the bottom part 141 was 3 mm, uneven coating was confirmed. However, when the thickness T was 1 mm, uneven coating was not confirmed. Therefore, the thickness (T) of the bottom part 141 is preferably less than 3 mm and is more preferably 1 mm or less.

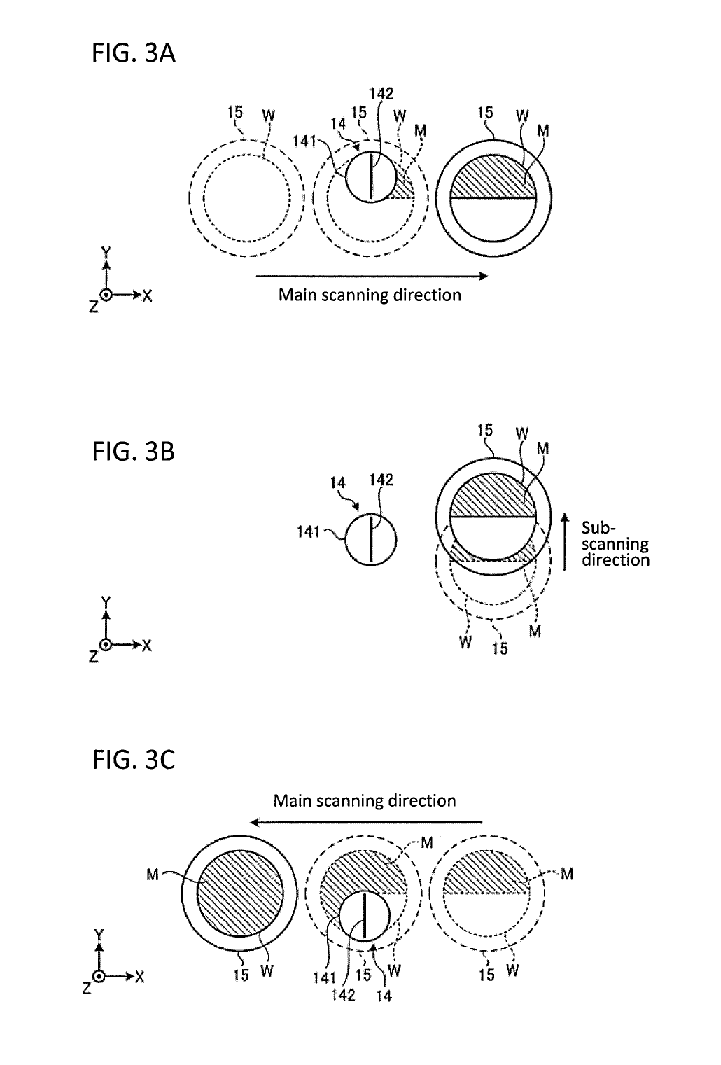

Scan coating operations by the film-forming apparatus 1 are described using FIG. 3A-3C. FIG. 3A-3C illustrate schematic diagrams illustrating operation examples of scan coating operations.

As illustrated in FIG. 3A, the film-forming apparatus 1 moves the stage 15 in the main scanning direction, that is, a direction orthogonal to an extension direction of the discharge port 142 in a state in which the fine particles of the organic material are discharged from the discharge port 142. As a result, the fine particles of the organic material are attached to the surface of the substrate (W) and an organic thin film (M) is formed. Here, an example is illustrated of a case where the organic thin film (M) is formed on one half of the surface of the substrate (W) by one scan coating operation.

As illustrated in FIG. 3B, the film-forming apparatus 1 aligns a position of the discharge port 142 with respect to a portion of the surface of the substrate (W) on which application of the fine particles has not been performed, by moving the stage 15 in the sub-scanning direction, that is, a direction parallel to the extension direction of the discharge port 142.

As illustrated in FIG. 3C, the film-forming apparatus 1 again moves the stage 15 in the main scanning direction. As a result, the fine particles of the organic material are attached to the entire surface of the substrate (W) and the organic thin film (M) is formed on the entire surface of the substrate (W).

As described above, in the film-forming apparatus 1 according to the first embodiment, the nozzle 14 having the slit-shaped discharge port 142 is used to perform the scan coating to the substrate (W). Therefore, coating in a broad area can be performed in one scan coating operation.

Since coating in a broad area can be performed in one scan coating operation, as compared to a case where coating is performed using a nozzle that has a circular discharge port, the number of scan coating operations can be reduced and occurrence of uneven coating due to overlapping coating or coating failure can be suppressed.

Here, an example is illustrated of a case where the fine particles of the organic material are applied to the entire surface of the substrate (W) by two scan coating operations. However, the number of the scan coating operations varies depending on a diameter of the substrate (W) to be processed, a slit length of the discharge port 142, and the like, and is not limited to two.

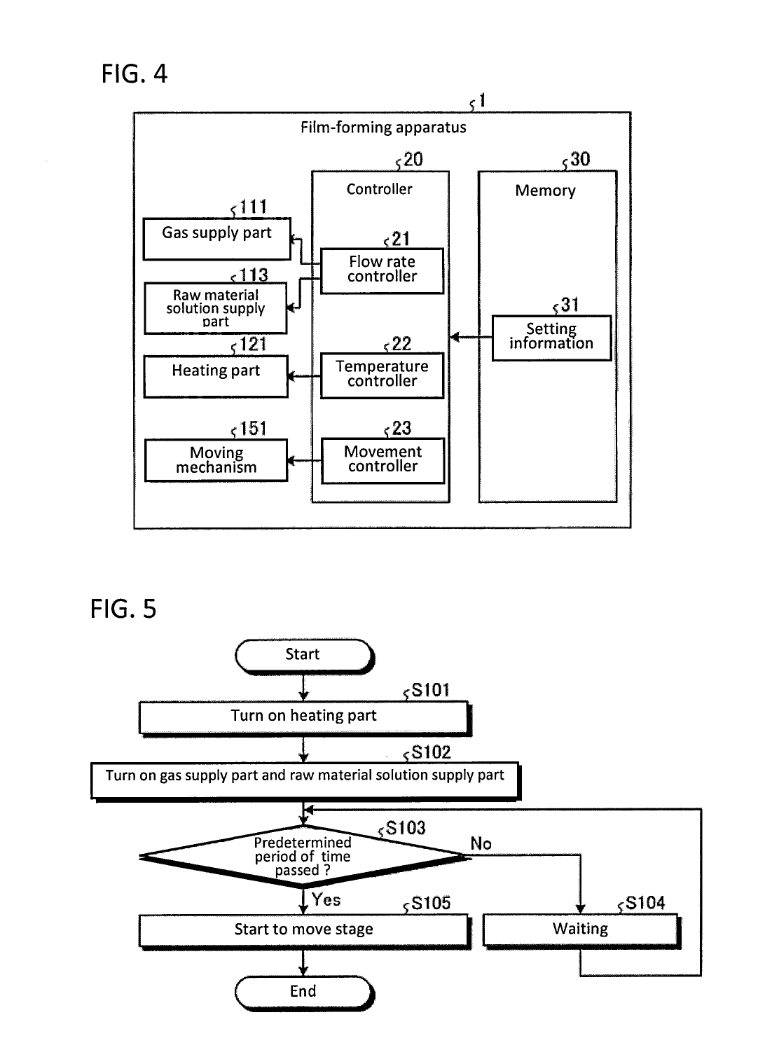

The structure of the film-forming apparatus 1 is described using FIG. 4. FIG. 4 illustrates a block diagram of the film-forming apparatus 1. In FIG. 4, structural elements for describing features of the film-forming apparatus 1 are illustrated; and description for general structural elements is omitted.

As illustrated in FIG. 4, the film-forming apparatus 1 includes the gas supply part 111, the raw material solution supply part 113, the heating part 121, a moving mechanism 151, a controller 20 and a memory 30. Further, the controller 20 includes a flow rate controller 21, a temperature controller 22 and a movement controller 23. The memory 30 stores setting information 31.

In addition to the structural elements illustrated in FIG. 4, the film-forming apparatus 1 also includes the raw material solution storage part 112, the spraying device 117, the first chamber 12, the nozzle 14, and the like that are illustrated in FIG. 1, but these are omitted in FIG. 4.

The moving mechanism 151 moves the stage 15 in horizontal directions, specifically, the main scanning direction (X-axis direction) and the sub-scanning direction (Y-axis direction). This allows the position of the discharge port 142 of the nozzle 14 to relatively change along the surface of the substrate (W) that is placed on the stage 15.

The moving mechanism 151 can also move the stage 15 in the vertical direction (Z-axis direction). This allows a distance between the surface of the substrate (W) and the nozzle 14 to change.

The moving mechanism 151 includes a drive source such as a motor and uses the drive source to move the stage 15.

The controller 20 is a controller that controls the whole film-forming apparatus 1, and includes the flow rate controller 21, the temperature controller 22 and the movement controller 23.

The flow rate controller 21 is a processing part that controls the flow rate of the carrier gas that is supplied from the gas supply part 111 to the spraying device 117 by controlling the controller of the gas supply part 111.

The flow rate of the carrier gas is controlled by the flow rate controller 21. Thereby, the flow rate and the pressure of the carrier gas are ensured that allow the fine particles of the organic material to be guided from the front end part of the first chamber 12 to the surface of the substrate (W).

The flow rate controller 21 also performs processing that controls a flow rate of the raw material solution that is supplied from the raw material solution storage part 112 to the spraying device 117 by controlling the controller of the raw material solution supply part 113. The flow rate controller 21 determines the flow rates of the carrier gas and the raw material solution according to the setting information 31 stored in the memory 30.

The temperature controller 22 is a processing part that controls a heating temperature due to the heating part 121. The heating temperature is controlled by the temperature controller 22. Thereby, the temperature in the first chamber 12 is maintained at the temperature suitable for the vaporization of the solvent contained in the aerosol (S). The temperature controller 22 determines the heating temperature according to the setting information 31 stored in the memory 30.

The movement controller 23 is a processing part that controls the movement of the stage 15 by controlling the drive source of the moving mechanism 151. The moving mechanism 151 is controlled by the movement controller 23. Thereby, the movement of the stage 15 in the horizontal directions (the main scanning direction and the sub-scanning direction) and the vertical direction is controlled.

The memory 30 is storage device such as a nonvolatile memory or a hard disk drive, and stores the setting information 31. The setting information 31 is information that includes the flow rate of the carrier gas, the flow rate of the raw material solution, the heating temperature due to the heating part 121, the distance between the nozzle 14 and the stage 15, a movement speed of the stage 15, and the like. The setting information 31 may be appropriately changed by an operation from a user.

A specific operation of the film-forming apparatus 1 is described using FIG. 5. FIG. 5 illustrates a flow chart illustrating processing steps of a film-forming process that the film-forming apparatus 1 executes.

As illustrated in FIG. 5, first, the temperature controller 22 turns on the heating part 121 (S101); and the flow rate controller 21 turns on the gas supply part 111 and the raw material solution supply part 113 (S102). As a result, heating by the heating part 121 is started, and supply of the carrier gas and the raw material solution to the spraying device 117 is started and the fine particles of the organic material begin to be discharged from the nozzle 14.

The controller 20 judges whether or not a predetermined period of time has passed since the heating part 121, the gas supply part 111 and the raw material solution supply part 113 are turned on (S103), and, when the predetermined period of time has not passed (No at S103), waits until the predetermined period of time has passed (S104). When the film-forming apparatus 1 is waiting, the stage 15 is in a state being retreated to a position where the fine particles discharged from the nozzle 14 are not applied to the substrate (W).

Immediately after the heating part 121, the gas supply part 111 and the raw material solution supply part 113 are turned on, there is a possibility that particle diameters and a discharge rate of the fine particles of the organic material are not stable and uneven coating occurs on the surface of the substrate (W). Therefore, after the heating part 121, the gas supply part 111 and the raw material solution supply part 113 are turned on, the film-forming apparatus 1 does not start the scan coating operation until the predetermined period of time has passed. Thereby, occurrence of the uneven coating can be prevented. The above-described predetermined period of time is, for example, 10 seconds.

At S103, when it is judged that the predetermined period of time has passed (Yes at S103), the movement controller 23 starts to move the stage 15 by controlling the moving mechanism 151 (S105). As a result, the scan coating operations illustrated in FIG. 3A-3C are executed.

The film-forming apparatus 1 according to the first embodiment includes the aerosol generation part 11, the first chamber 12, the nozzle 14 and the moving mechanism 151. The aerosol generation part 11 generates the aerosol (S) that is obtained by dispersing the solution of the raw material that is the film-forming material in the carrier gas. In the first chamber 12, the aerosol (S) that is generated by the aerosol generation part 11 is supplied from the base end part, and, by vaporizing the supplied aerosol (S), the fine particles of the organic material that is the film-forming material are generated. The nozzle 14 discharges toward the substrate (W) the fine particles that are released from the front end part of the first chamber 12. The moving mechanism 151 relatively moves the nozzle 14 and the substrate (W) along the surface of the substrate (W).

The nozzle 14 has the discharge port 142 for the fine particles in the slit-shaped region (R) that extends in a direction orthogonal to the direction of the movement due to the moving mechanism 151. Therefore, according to the film-forming apparatus 1 of the first embodiment, coating efficiency can be improved.

According to a film-forming method that the film-forming apparatus 1 executes, an organic thin film can be formed even without conditions such as high temperature and vacuum.

For example, from a raw material solution that is obtained by dissolving or dispersing in a solvent a polymer material for which film formation using a vacuum deposition method is difficult, a metal complex that changes in quality when heated, and the like, a thin film of these organic materials can be formed. Further, even from an aerosol that is formed from a dilute raw material solution of 0.1% or less for which film formation in a wet process is difficult, by performing vaporization of the solvent before attaching the organic material to the substrate, an organic thin film that can be used for an organic EL element can be formed.

### Second Embodiment

In the above-described first embodiment, an example is described of a case where the film-forming apparatus includes one nozzle. However, a film-forming apparatus can also use multiple nozzles to form a thin film of multiple layers on the surface of the substrate (W) in one scan coating operation. In the following, an example is described of a case where a film-forming apparatus includes multiple nozzles.

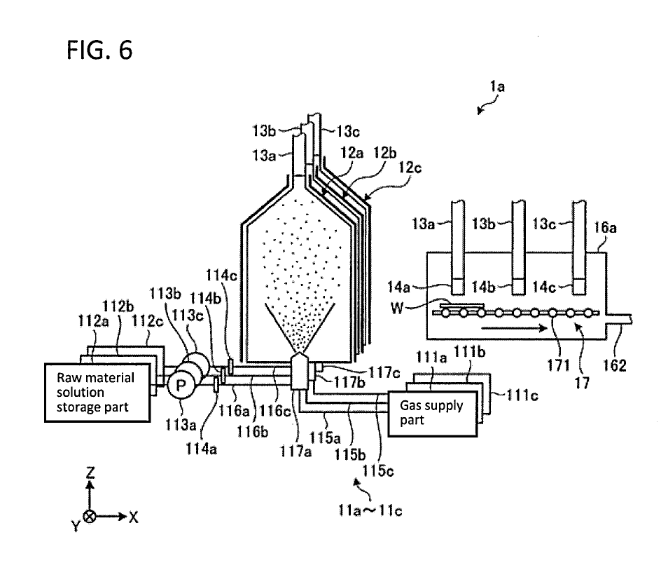

A structure of a film-forming apparatus according to a second embodiment is described using FIG. 6. FIG. 6 illustrates a schematic diagram illustrating the structure of the film-forming apparatus according to the second embodiment. In the following description, a part that is the same as a part that has already been described is indicated using the reference numeral symbol as the part that has already been described, and redundant description is omitted.

As illustrated in FIG. 6, a film-forming apparatus 1a according to the second embodiment includes a substrate carrying part 17 (corresponding to a moving mechanism). The substrate carrying part 17 is, for example, a roller conveyor, and, by rotating a large number of rollers 171, carries the substrate (W) that is placed on the rollers 171 in the main scanning direction (X-axis direction). The substrate carrying part 17 has a heating mechanism (not illustrated in FIG. 6) such as a heater, and is capable of carrying the substrate (W) while heating the substrate (W).

The film-forming apparatus 1a according to the second embodiment includes three nozzles (14a, 14b, 14c). The nozzles (14a, 14b, 14c) are each the same as the nozzle 14 (FIGS. 2A and 2B) according to the first embodiment.

The nozzles (14a, 14b, 14c) are each arranged above the substrate carrying part 17 in a state in which the discharge port is oriented toward a carrying surface of the substrate carrying part 17, and are arranged side by side at equal intervals along the main scanning direction. Further, similar to the first embodiment, a discharge port that is formed on each of the nozzles (14a, 14b, 14c) extends in a direction orthogonal to the main scanning direction.

The nozzles (14a, 14b, 14c), the substrate carrying part 17 and the substrate (W) are arranged in a second chamber (16a). Similar to the second chamber 16 according to the first embodiment, the second chamber (16a) includes an exhaust part 162. From the exhaust part 162, the carrier gas, the fine particles of the organic material that are not applied to the substrate (W), and the like, are discharged.

The nozzles (14a, 14b, 14c) are respectively connected via pipes (13a-13c) to front end parts of first chambers (12a-12c). Further, for the first chambers (12a-12c), aerosol generation parts (11a-11c) are respectively provided.

The aerosol generation parts (11a-11c) respectively include gas supply parts (111a-111c), raw material solution storage parts (112a-112c), raw material solution supply parts (113a-113c), filters (114a-114c), pipes (115a-115c, 116a-116c) and spraying devices (117a-117c).

In the raw material solution storage part (112a-112c), raw material solutions that contain different organic materials are respectively stored. This allows aerosols containing different organic materials to be respectively supplied to the first chambers (12a-12c). As a result, fine particles of different organic materials are respectively supplied to the nozzles (14a-14c).

As described above, in the second embodiment, the nozzles (14a, 14b, 14c) are respectively connected to the different first chambers (12a-12c), and respectively discharge the fine particles of the different organic materials toward the substrate (W).

Structure of the aerosol generation parts (11a-11c), the first chambers (12a-12c) and the pipes (13a-13c) are the same as the aerosol generation part 11, the first chamber 12 and the pipe 13 according to the first embodiment and thus descriptions thereof are omitted here.

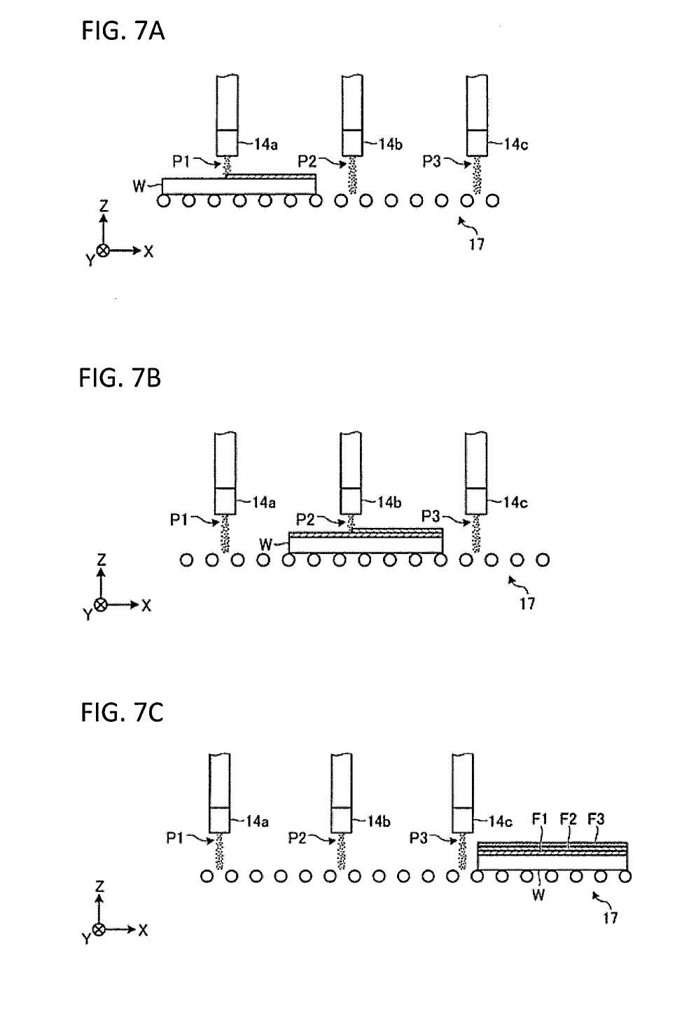

An operation of the film-forming apparatus 1a according to the second embodiment is described using FIG. 7A-7C. FIG. 7A-7C illustrate schematic diagrams illustrating operation examples of scan coating operations according to the second embodiment.

The film-forming apparatus 1a drives the substrate carrying part 17 to carry the substrate (W) in the main scanning direction (X-axis direction) in a state in which fine particles (P1-P3) of the different organic materials are respectively discharged from the discharge ports of the nozzles (14a-14c).

As a result, as illustrated in FIG. 7A-7C, the fine particles (P1) of the organic material that are discharged from the nozzle (14a), the fine particles (P2) of the organic material that are discharged from the nozzle (14b) and the fine particles (P3) of the organic material that are discharged from the nozzle (14c) are respectively applied in this order on the surface of the substrate (W). As a result, on the surface of the substrate (W), three kinds of organic thin films (F1-F3) are formed in laminated layers by one scan coating operation.

According to a film-forming method that the film-forming apparatuses (1, 1a) execute, multiple organic thin films can be laminated without causing interlayer mixing. Therefore, as in the film-forming apparatus 1a according to the second embodiment, the fine particles (P1-P3) of the plurality of the organic materials can be applied in one scan coating operation.

In the second embodiment, the film-forming apparatus 1a includes the plurality of the nozzles (14a, 14b, 14c) that are arranged along the direction of the movement due to the substrate carrying part 17. Therefore, the fine particles of the plurality of the organic materials can be applied in one scan coating operation. Therefore, when multiple thin films are formed on one substrate (W), for example, since there is no need to perform a setup change for the nozzle, time required for film formation can be shortened.

In the above-described second embodiment, an example is described of a case where the film-forming apparatus includes three nozzles. However, the number of the nozzles that the film-forming apparatus includes may be two or may be four or more.

In the above-described second embodiment, an example is described of a case where fine particles of different kinds of organic materials are respectively discharged from the nozzles. However, in a film-forming apparatus, it is also possible that fine particles of a same organic material are discharged from at least two of multiple nozzles. In this case, the nozzles from which the fine particles of the same organic material are discharged may be connected to a same first chamber.

### Third Embodiment

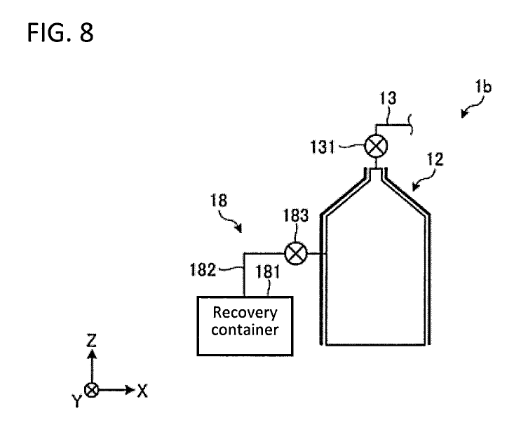

The film-forming apparatus may include a recovery part that recovers the aerosol or the fine particles of the organic material in the first chamber. In the following, an example of a case where the film-forming apparatus includes a recovery part is described using FIG. 8. FIG. 8 illustrates a schematic diagram illustrating a connection relationship between a first chamber and a recovery part according to a third embodiment.

As illustrated in FIG. 8, a film-forming apparatus (1b) according to the third embodiment further includes a recovery part 18. The recovery part 18 includes a recovery container 181, a pipe 182 and a valve 183. The recovery container 181 is a container in which an aerosol or fine particles of an organic material that are recovered from the first chamber 12 are stored. The recovery container 181 is connected via the pipe 182 to the first chamber 12.

At a middle portion of the pipe 182, the valve 183 is provided. Further, also at a middle portion of the pipe 13 that is connected to the front end part of the first chamber 12, a valve 131 is provided. Opening and closing of these valves (131, 183) are controlled by a controller of the film-forming apparatus (1b).

Immediately after the heating part 121, the gas supply part 111 and the raw material solution supply part 113 (see FIG. 1) are turned on, the particle diameters and the discharge rate of the fine particles of the organic material are unlikely to be stable. Therefore, it is conceivable that, by keeping the heating part 121, the gas supply part 111 and the raw material solution supply part 113 (see FIG. 1) in an always-on state, waiting time until the particle diameters and the discharge rate of the fine particles of the organic material become stable is reduced. However, an amount of the raw material solution that is wastefully consumed is increased.

The controller of the film-forming apparatus (1b) according to the third embodiment closes the valve 131 and opens the valve 183 during a period of time from when a last scan coating operation with respect to one substrate (W) is completed to when an initial scan coating operation with respect to a next substrate (W) is started. As a result, the aerosol that is supplied into the first chamber 12 and the fine particles of the organic material that are generated in the first chamber 12 are recovered via the pipe 182 to the recovery container 181 and thus that the aerosol and the fine particles of the organic material are wastefully consumed can be prevented.

The controller of the film-forming apparatus (1b) opens the valve 131 and closes the valve 183 at a timing when the initial scan coating operation with respect to the next substrate (W) is started. As a result, from the nozzle 14, the fine particles of the organic material are discharged. In the third embodiment, the heating part 121, the gas supply part 111 and the raw material solution supply part 113 (see FIG. 1) are kept in an always-on state. Therefore, the fine particles of the organic material are discharged in a state in which the particle diameters and the discharge rate are stable. Therefore, the film-forming apparatus (1b) does not need to wait to start a scan coating operation until the particle diameters and the discharge rate of the fine particles of the organic material become stable.

The film-forming apparatus (1b) according to the third embodiment further includes the recovery part 18 that is connected to the first chamber 12 and recovers the aerosol or the fine particles of the organic material in the first chamber 12. Therefore, even when generation of the aerosol by the aerosol generation part 11 is constantly performed, waste of the raw material solution can be suppressed.

### Fourth Embodiment

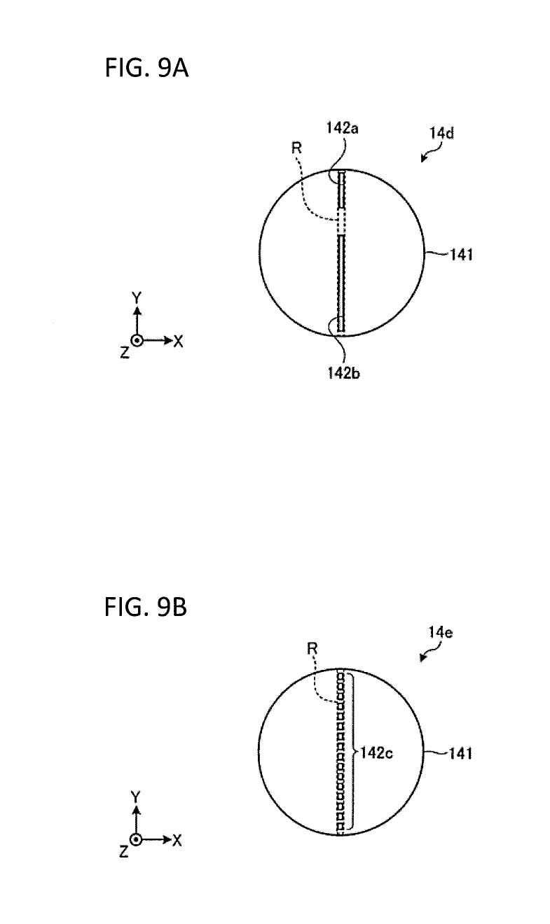

The shape of the discharge port that is formed on the nozzle is not necessarily limited to the shape illustrated in FIG. 2A. In the following, other examples of the shape of the discharge port are described using FIGS. 9A and 9B. FIGS. 9A and 9B illustrate schematic plan views illustrating other shapes of nozzles.

For example, as illustrated in FIG. 9A, it is also possible that a nozzle (14d) has two discharge ports (142a, 142b) in a slit-shaped region (R). Here, an example is described of a case where the two discharge ports (142a, 142b) are formed. However, it is also possible that two or more discharge ports are formed in the slit-shaped region (R).

It is not necessary that a discharge port is formed in a shape extending in the sub-scanning direction (Y-axis direction). For example, as illustrated in FIG. 9B, a nozzle (14e) includes a large number of discharge ports (142c) in a slit-shaped region (R). It is also possible that each of the discharge ports (142c) in this case has a shape such that a length in the sub-scanning direction (Y-axis direction) and a length in the main scanning direction (X-axis direction) are the same, or the length in the main scanning direction is longer.

As described above, a discharge port may be formed in any shape as long as the discharge port is formed in the slit-shaped region (R) that extends in a direction orthogonal to the main scanning direction.

In the above-described embodiments, as illustrated in FIG. 2B, an example is described of a case where a nozzle has cylindrical body part. However, it is also possible that a body part of a nozzle has a non-cylindrical shape. For example, it is also possible that a body part of a nozzle has a tapered shape in which an inner diameter on a discharge port side is smaller than an inner diameter on a pipe side.

In the above-described embodiments, an example is described of a case where the film-forming apparatus forms on a substrate an organic thin film that forms an organic EL element. However, the film-forming apparatus is not limited to the organic EL element, but is also applicable to cases where organic thin films forms other organic devices such as an organic FET (Field-Effect Transistor) and an organic optoelectronic conversion element.

In the above-described embodiments, an example is described of a case where an organic thin film is formed on a substrate using a moving mechanism to move the substrate. However, it is also possible that the film-forming apparatus forms an organic thin film on a substrate using a moving mechanism to move the nozzle. That is, the moving mechanism may be any mechanism that relatively moves the nozzle and the substrate along a surface of the substrate. However, when the nozzle is moved, due to deformation of the pipe that is connected to the nozzle, there is a possibility that turbulence occurs in the flow of the fine particles that move in the pipe. Therefore, it is preferable that the film-forming apparatus move the substrate rather than the nozzle.

When the discharge port that is formed on the nozzle has a circular shape, it is difficult to perform coating in a broad area in one scan coating operation.

A film-forming apparatus and a film-forming method according to an embodiment of the present invention can improve coating efficiency.

A film-forming apparatus according to an embodiment of the present invention includes an aerosol generation part, a chamber, a nozzle and a moving mechanism. The aerosol generation part generates an aerosol that is obtained by dispersing a solution of a film-forming material in a carrier gas. In the chamber, the aerosol that is generated by the aerosol generation part is supplied from a base end part, and, by vaporizing the supplied aerosol, fine particles of the film-forming material are generated. The nozzle discharges toward a substrate the fine particles that are released from a front end part of the chamber. The moving mechanism relatively moves the nozzle and a substrate along a surface of the substrate. Further, the nozzle has a discharge port for the fine particles in a slit-shaped region that extends in a direction orthogonal to a direction of movement due to the moving mechanism.

According to an embodiment of the present invention, coating efficiency can be improved.

Obviously, numerous modifications and variations of the present invention are possible in light of the above teachings. It is therefore to be understood that within the scope of the appended claims, the invention may be practiced otherwise than as specifically described herein.

What is claimed is:

1. A film-forming apparatus, comprising:
an aerosol generation device configured to generate an aerosol comprising a solution of a film-forming material dispersed in a carrier gas;
a chamber configured to vaporize the aerosol such that fine particles of the film-forming material are generated from the aerosol that is generated by the aerosol generation device;
a nozzle configured to discharge the fine particles generated by the chamber toward a substrate; and
a moving mechanism configured to execute relative movement of the nozzle and the substrate along a surface of the substrate,
wherein the nozzle has a discharge port configured to discharge the fine particles to a slit-shaped region extending in a direction orthogonal to a moving direction of the relative movement between the nozzle and the substrate executed by the moving mechanism.

2. A film-forming apparatus according to claim 1, further comprising:
a pipe device having one end connected to a front end portion of the chamber and another end portion connected to the nozzle,
wherein the nozzle has a bottomed cylindrical shape having an inner diameter substantially equal to an inner diameter of the pipe device, and the discharge port of the nozzle is formed in a bottom portion of the nozzle.

3. A film-forming apparatus according to claim 2, wherein the bottom portion of the nozzle has a thickness which is less than 3 mm.

4. A film-forming apparatus according to claim 1, wherein the nozzle is provided in a plurality such that the plurality of nozzles is positioned along the moving direction of the relative movement between the nozzle and the substrate executed by the moving mechanism.

5. A film-forming apparatus according to claim 2, wherein the nozzle is provided in a plurality such that the plurality of nozzles is positioned along the moving direction of the relative movement between the nozzle and the substrate executed by the moving mechanism.

6. A film-forming apparatus according to claim 3, wherein the nozzle is provided in a plurality such that the plurality of nozzles is positioned along the moving direction of the relative movement between the nozzle and the substrate executed by the moving mechanism.

7. A film-forming apparatus according to claim 1, further comprising:
a recovery device connected to the chamber and configured to recover at least one of the aerosol and the fine particles of the film-forming material inside the chamber.

8. A film-forming apparatus according to claim 2, further comprising:
a recovery device connected to the chamber and configured to recover at least one of the aerosol and the fine particles of the film-forming material inside the chamber.

9. A film-forming apparatus according to claim 3, further comprising:
a recovery device connected to the chamber and configured to recover at least one of the aerosol and the fine particles of the film-forming material inside the chamber.

10. A film-forming apparatus according to claim 1, wherein the chamber has a base end portion configured to receive the aerosol generated by the aerosol generation device, and the chamber is positioned such that the based end portion forms a bottom portion of the chamber.

11. A film-forming apparatus according to claim 2, wherein the chamber has a base end portion configured to receive the aerosol generated by the aerosol generation device, and the chamber is positioned such that the based end portion forms a bottom portion of the chamber.

12. A film-forming apparatus according to claim 3, wherein the chamber has a base end portion configured to receive the aerosol generated by the aerosol generation device, and the chamber is positioned such that the based end portion forms a bottom portion of the chamber.

13. A film-forming apparatus according to claim 1, wherein the chamber has a base end portion configured to receive the aerosol generated by the aerosol generation device and a front end portion configured to discharge the fine particles of the film-forming material toward the nozzle.

14. A film-forming apparatus according to claim 1, further comprising:
a stage configured to hold the substrate,
wherein the moving mechanism is configured to move the stage such that the nozzle applies the fine particles of the film-forming material by scan coating with respect to the substrate.

15. A film-forming apparatus according to claim 1, wherein the discharge port of the nozzle has a slit shape.

16. A method for forming a film, comprising:
generating an aerosol comprising a solution of a film-forming material dispersed in a carrier gas by an aerosol generation device;
vaporizing the aerosol in a chamber such that fine particles of the film-forming material is generated from the aerosol that is generated by the aerosol generation device; and
discharging the fine particles generated by the chamber from a nozzle toward a substrate,
wherein the discharging of the fine particles includes discharging the fine particles to a slit-shaped region extending in a direction orthogonal to a movement direction of relative movement of the nozzle and the substrate while a moving mechanism executes the relative movement of the nozzle and the substrate along a surface of the substrate.

17. A method for forming a film according to claim 16, further comprising:
recovering at least one of the aerosol and the fine particles of the film-forming material inside the chamber by a recovery device connected to the chamber.

18. A method for forming a film according to claim 16, wherein the chamber has a base end portion configured to receive the aerosol generated by the aerosol generation device and a front end portion configured to discharge the fine particles of the film-forming material toward the nozzle.

19. A method for forming a film according to claim 16, wherein the discharging of the fine particles includes applying the fine particles of the film-forming material by scan coating with respect to the substrate through the nozzle while the moving mechanism is moving the substrate held by a stage.

20. A method for forming a film according to claim 16, wherein the discharging of the fine particles includes discharging the fine particles of the film-forming material from a discharge port of the nozzle, and the discharge port of the nozzle has a slit shape.
